(19) United States
(12) Patent Application Publication
(10) Pub. No.: US 2005/0139984 A1
(43) Pub. Date: Jun. 30, 2005

(54) Package element and packaged chip having severable electrically conductive ties

(75) Inventors: David B. Tuckerman, Orinda, CA (US); Richard Dewitt Crisp, Castro Valley, CA (US); Belgacem Haba, Cupertino, CA (US); Giles Humpston, San Jose, CA (US); Jae M. Park, San Jose, CA (US)

Correspondence Address: LERNER DAVID, LITENBERG, KRUMHOLZ & MENTLIK, 600 SOUTH AVENUE WEST, WESTFIELD, NJ, 07090, US

(73) Assignee: Tessera, Inc., San Jose, CA (US)

(21) Appl. No.: 11/016,034

(22) Filed: Dec. 17, 2004

Related U.S. Application Data
(60) Provisional application No. 60/531,030, filed on Dec. 19, 2003.

(51) Int. Cl. H01L 21/00; H01L 21/50; H01L 23/52

(52) U.S. Cl. 257/693; 438/51; 438/25; 438/26

(57) ABSTRACT

According to one aspect of the invention, a capped chip is provided which includes a chip having a front surface, a back surface opposite the front surface and a plurality of bond pads exposed at at least one of the front and back surfaces. A cap is joined to the chip, the cap overlying one of the front and back surfaces of the chip. The cap includes a plurality of contacts which are conductively interconnected to the bond pads, and one or more temporary ties which conductively connect two or more of the contacts. The temporary ties are severable after the contacts are conductively interconnected to the bond pads.

### CROSS-REFERENCE TO RELATED APPLICATIONS

This application claims the benefit of the filing date of U.S. Provisional Application No. 60/531,030 filed Dec. 19, 2003, the disclosure of which is hereby incorporated by reference herein.

### BACKGROUND OF THE INVENTION

The present invention relates to the packaging of microelectronic elements, e.g., chips, and micro-electromechanical (MEMs) devices.

In fabricating integrated circuits, also referred to herein as “chips”, protecting the delicate structures that make up the chips are a monumental concern. This is particularly true for chips that are vulnerable to certain environments. For example, chips which include electrical, micro-electromechanical (MEMs) devices or optical components have delicate structures which need to be protected from contamination and other damage.

The functionality of many types of electronic systems, for example, radio transmitters and receivers that are operated at a radio frequency (RF), is improved if the circuit contains filters at particular locations to help resolve wanted signals from unwanted signals and noise. There are many methods of realizing filters for electronic signals, including resistor-capacitor-inductor networks, micro-electromechanical devices, also known as “MEMs” devices, and active circuits. Such circuits and corresponding components are quite delicate. Of particular interest to mobile telephone applications are micro-electromechanical filters or “MEMs filters”. These offer an attractive trade-off in terms of performance, size and manufacturing cost. The two principal types of MEMs filters are Surface Acoustic Wave (SAW) filters or devices and Thin Film Bulk Acoustic Resonators (FBAR).

At a simplistic level, a MEMs filter can be considered as a miniaturized tuning fork. The incoming electrical signals are converted to a mechanical motion and then back to an electrical signal. The mechanical structure is designed to have a narrow passband characterized by a resonant frequency so that electrical signals which match the resonant frequency pass through the component largely un-attenuated, while signals other than the resonant frequency are rejected, i.e., greatly diminished in amplitude.

A SAW filter is realized by forming two or more electrode structures on the surface of a piezo-electrically active material, such as lithium tantalate, quartz, aluminum nitride or diamond. A piezoelectric material changes its physical dimension in response to an applied electric field and thereby provides electrical-to-mechanical conversion and vice versa. The speed at which pressure waves propagate through the piezoelectric material and the spacing between the set of electrodes sets the operational frequency of the device.

Some types of integrated circuits, i.e., chips, are especially delicate, being sensitive to heat, jarring material strain, and other factors that stress their components. For such circuits, it is not only desirable, but may be essential to take special precautions during the manufacture of such chips to prevent catastrophic failure. An example of a sensitive device that requires extraordinary care during the packaging process is a SAW device. A SAW device typically comprises a very fine electrode structure on the surface of a piezoelectric material such as lithium tantalate. The structure usually has very closely spaced fingers of electrodes, which may be interdigitated. Due to such structure, the breakdown voltage between adjacent fingers of a SAW device is small. Sensitive circuits like SAW devices are typically fabricated in piezoelectric materials, which exhibit an external electric field when a mechanical stress is applied to the material. A charge flow may be observed when a closed circuit is attached to electrodes on the surface of the material when stress is applied. Piezoelectric materials further possess pyroelectric properties. Pyroelectric properties cause thermal excursions in a SAW device when the device is stressed during wafer processing. These thermal excursions generate charges that can destroy SAW devices. SAW devices must undergo a number of thermal excursions during processing and packaging, SAW devices are at risk of catastrophic failure from electrostatic discharge (ESD) during such processing and packaging. There are several conventional attempts to mitigate this problem, but they each have shortcomings.

One approach to mitigating this problem is to invoke process restrictions. The magnitude of the charge developed depends, to a certain extent, on the rate of heating or cooling as the charge slowly dissipates due to leakage through the substrate and across its surface. Restricting the maximum rate of temperature change during processing helps prevent excessive charge being developed. Unfortunately, such restrictions limit equipment throughput and may compromise the effectiveness of other processes, such as soldering, that function best when the temperature excursion is rapid.

Another approach is to limit substrate leakage by using a substrate material having low resistivity. This allows the charge developed by the pyroelectric effect to be limited for a given rate of temperature change. This is typically achieved by incorporating a dopant into the substrate. However, because the resistivity of the substrate material affects the efficiency of conversion of electrical charge to mechanical displacement, doped substrates have lower piezoelectric coefficients. This makes them less useful for SAW device and other sensitive circuit applications.

Still another approach is illustrated in a plan view of a SAW device chip shown in FIG. 1. As shown therein, a set of interdigitated fingers 24 of the SAW device chip 10 are conductively connected to respective bond pads 26 of the chip through traces 20. The part of a SAW device most vulnerable to damage from (ESD) are these fingers of the SAW device chip. This is a result of the small spacing between adjacent fingers, often 0.5 μm or less. In operation, signals, power and ground connections to the fingers 24 are provided through the bond pads 26 and the traces 20. As protection from damaging pyroelectric currents during manufacture, the SAW device chip 10 includes a set of temporary conductive ties 22. Typically, patterning of one or more metal layers to form the SAW device structure also patterns a set of conductive ties which link all of the external bond pads of the SAW device together, typically through a guard ring that lies inside dicing lanes between adjacent chips of the wafer. When the SAW device chip 10 remains attached to other chips in wafer form, the temporary conductive ties 22 are conductively connected together through the metallic guard ring 28. The temporary conductive ties 22 and the guard ring 28 have low impedance at frequencies in which pyroelectric effects during manufacturing are most likely to be observed. This property allows the guard ring and temporary ties to protect the SAW device on the chip 10 from damaging electrostatic discharges, as the electric potential at every bond pad and at every interdigitated finger 24 is maintained essentially the same at every point on the chip.

As further shown in FIG. 1, the guard ring 28 is typically located in the “dicing lane” 34, i.e., the location of the kerf that results from the wafer being subsequently sawn into individual chips. Such dicing lane extends from a peripheral edge 30 of the one chip of the wafer and peripheral edges 32 other chips 12 adjacent to the one chip 10, as will exist when the wafer is sawn into individual chips. Placement of the guard ring 28 in the dicing lane 34 assures that the guard ring 28 will be severed upon severing the wafer into individual chips, which in turn electrically disconnects the temporary conductive ties from each other.

However, in conventional processes, the stubs of the tie-bar connections between the bond pads and the common guard ring have an undesirable influence upon the behavior of the chip in the RF domain that adversely affects the performance of the filter employing a SAW device.

Accordingly, there exists a need for an improved package element, packaged chip and method for packaging a chip which addresses the special vulnerabilities of SAW devices and other sensitive chips.

In addition, there exists a need for a cap or package element, capped chip and method for packaging a chip which facilitates the simultaneous assembly of a cap wafer having a large area to a device wafer or other multiple chip-containing substrate, which cap wafer addresses the special vulnerabilities of SAW devices and other sensitive chips.

### SUMMARY OF THE INVENTION

According to one aspect of the invention, a capped chip is provided which includes a chip having a front surface, a back surface opposite the front surface and a plurality of bond pads exposed at at least one of the front and back surfaces. A cap is joined to the chip, the cap overlying one of the front and back surfaces of the chip. The cap includes a plurality of contacts which are conductively interconnected to the bond pads, and one or more temporary ties which conductively connect two or more of the contacts. The temporary ties are severable after the contacts are conductively interconnected to the bond pads.

According to another aspect of the invention, a cap is provided which is adapted to at least partially cover and provide conductive interconnection to the chip. Such cap includes a plurality of contacts adapted to be conductively interconnected to bond pads of the chip, and one or more temporary ties which conductively connect two or more of the contacts. The temporary ties are severable after the contacts are conductively interconnected to the bond pads.

According to yet another aspect of the invention, a capped chip is provided which includes a chip having a front surface, a back surface opposite the front surface and a plurality of bond pads exposed at the front surface. A cap overlies and is joined to the front surface of the chip, the cap having a plurality of contacts conductively interconnected to the bond pads. The cap further includes one or more temporary ties which conductively connect two or more of the contacts, the temporary ties being severable after the contacts are conductively interconnected to the bond pads.

According to another aspect of the invention, a method is provided for fabricating capped chips. Such method includes aligning a cap element to a substrate including a plurality of chips attached to each other at dicing lanes defining boundaries between the chips, the chips having an outer surface between the dicing lanes and bond pads exposed at the outer surface, the cap element including a plurality of contacts and one or more temporary ties conductively interconnecting the contacts. The cap element is joined to the substrate and conductive interconnects are formed between the bond pads and the contacts to form capped chips. The one or more temporary ties of each chip are severed after forming the conductive interconnects.

### BRIEF DESCRIPTION OF THE DRAWINGS

FIG. 1 is a plan view illustrating a prior art SAW device wafer on which a set of conductive ties and a guard ring are provided.

FIG. 2A is a plan view illustrating an outer surface of a cap wafer according to one embodiment of the invention, on which a structure of interconnected temporary ties and a guard ring are disposed.

FIG. 2B is a plan view illustrating a corresponding SAW device wafer to which the cap wafer of FIG. 2A is be interconnected.

FIG. 3 is a sectional view illustrating a capped chip according to a specific embodiment of the invention, in which conductive interconnects extend through individual through holes of the cap wafer.

FIG. 4 is a first plan view illustrating an inner (chip facing) side of the cap wafer illustrated in FIG. 3.

FIG. 5 is a second plan view illustrating an outer (exterior facing) side of the cap wafer illustrated in FIG. 3.

FIGS. 6 and 7 are a top-down plan view and a corresponding sectional view illustrating an embodiment of a cap, according to a particular embodiment of the invention.

FIGS. 8 and 9 are a top-down plan view and a corresponding sectional view illustrating an embodiment of the cap illustrated in FIGS. 6 and 7, after a conductive bump is formed thereon.

FIG. 10 is a plan view illustrating an outer surface of a cap in accordance with yet another embodiment of the H invention.

FIGS. 11 and 12 are a sectional view and a corresponding plan view of a capped chip in accordance with a particular embodiment of the invention.

FIG. 13 is a top-down plan view of a cap wafer illustrating an embodiment in which both a guard ring and interconnecting tie bars are provided.

FIG. 14 is a plan view illustrating a cap wafer according to yet another embodiment in which caps include guard rings which are disposed between the dicing lanes of the chip.

### DETAILED DESCRIPTION

In the embodiments of the invention described herein, a way is provided for protecting SAW devices or other chips against electrostatic discharge (ESD) during steps of the packaging process by which protective caps are joined to the chips. As described in the background, in wafer form, SAW devices are susceptible to damage due to the pyroelectric properties of common substrate materials. The propensity for ESD within the interdigitated electrodes of a SAW device is decreased by providing conductive ties on the SAW device which tie all of the bond pads to a guard ring. When the joined structure of the cap wafer and SAW device wafer are singulated into individual units, the conductive ties are severed from the guard ring. However, the placement of such ties on the SAW device make them impossible to fully remove, such that the ties remain on the SAW device as undesirable stubs which are sources of electromagnetic interference.

The embodiments of the invention address this concern by placing temporary conductive ties and a guard ring structure on a cap wafer rather than on the SAW device chip. After the cap wafer is joined to the SAW device wafer, the temporary ties remain accessible. For that reason, the temporary ties and/or guard ring structure can then be removed, even completely removed in an appropriate case, by ways other than sawing a joined wafer assembly into individual capped chips. With the more thorough removal of the conductive ties, improved RF performance is achieved than in chips packaged in accordance with conventional methods. A guard ring provided on a cap of such cap wafer element may also be placed within the area defined by the peripheral edges of an individual singulated chip, effectively saving space on the wafer.

In a particular embodiment, the temporary ties used to make the conductive ties are soluble in a fusible conductive material such as a solder. In a particular form of this embodiment, the temporary ties are soluble in a solder used either to seal the package or attach the package to a substrate by a surface mount method, and the temporary ties are designed to be severed by dissolving into the solder during a solder bonding process.

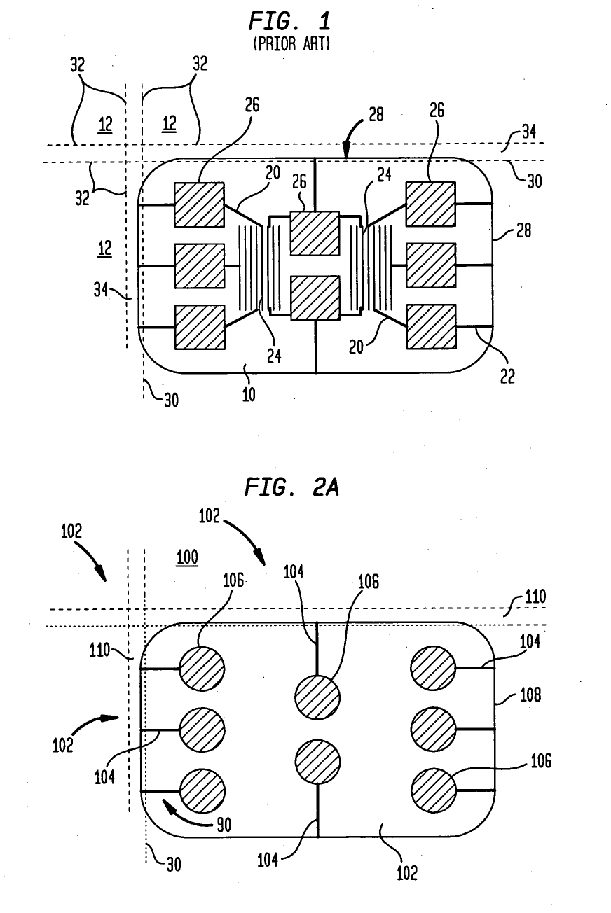

The embodiments of the invention will now be described with reference to FIGS. 2A-14. Accordingly, as shown in the plan view of FIG. 2A, in a first embodiment of the invention, a portion of a lid wafer or cap wafer including a plurality of lids or caps 102 mountable to a chip is shown, of which only one lid or cap 102 is shown in detail. Each lid or cap 102 (hereinafter, “cap”) includes a plurality of temporary conductive ties which conductively connect all of the contacts 106 of the cap 102 to a guard ring 108 disposed within dicing lanes 110 of the cap. At that time, the guard ring 108 conductively connects all of the contacts 106 of the cap 102 to each other, through the temporary ties which are provided on a surface of the cap. When the chip and the cap are thus joined together, with all of the temporary ties conductively connecting the contacts of the cap, the chip is in a condition which is at least partially, if not fully inoperative. The chip is fully operational only after the temporary ties are severed.

The cap wafer 100 shown in FIG. 2A is designed to be mounted over a contact-bearing surface of a wafer containing multiple chips, such as chips which are designed to transmit, receive or otherwise process radio frequency signals in the analog domain. In a particular example, the wafer contains SAW device chips 202, such as that shown in FIG. 2B. The SAW device chip 202 is similar to the chip 10 shown in FIG. 1, but has no temporary ties or guard ring. In this case, the SAW device chips need not have, and preferably do not have temporary ties such as those shown and described above with respect to FIG. 1, such ties conductively connecting the bond pads of the SAW device chip to each other. The elimination of the temporary ties from the SAW device chip leads to improved performance, because there will be no stubs on the SAW device chip which remain after the packaging process to impair the performance of the SAW device chip.

After such SAW device chip-containing wafer has been aligned and joined to the cap wafer, and suitable interconnections and processing have been performed, the two joined wafers are severed by sawing through dicing lanes 110. When the cap 102 remains attached to other caps in form of a cap wafer, the temporary conductive ties 104 are conductively connected together through the metallic guard ring 108, having low impedance at frequencies in which pyroelectric effects during manufacturing are most likely to be observed. This property allows the guard ring and temporary ties 108 for each cap 102 of the cap wafer 100 to protect the SAW device from damaging electrostatic discharges, as the contacts 106 of cap 102 are connected to corresponding bond pads of a SAW device chip.

By the herein described processes, the temporary ties and the guard ring can be formed on the cap portion of a capped chip in a number of different configurations and by a number of different processes, without concern for leaving residual tie bars behind as is the case when the tie bars are provided on the SAW device chip (FIG. 1). Here, with the tie bars and guard ring formed on a cap wafer, as described in at least some of the embodiments, all of the temporary ties and guard ring can be completely removed after the chip has been joined to cap assembly.

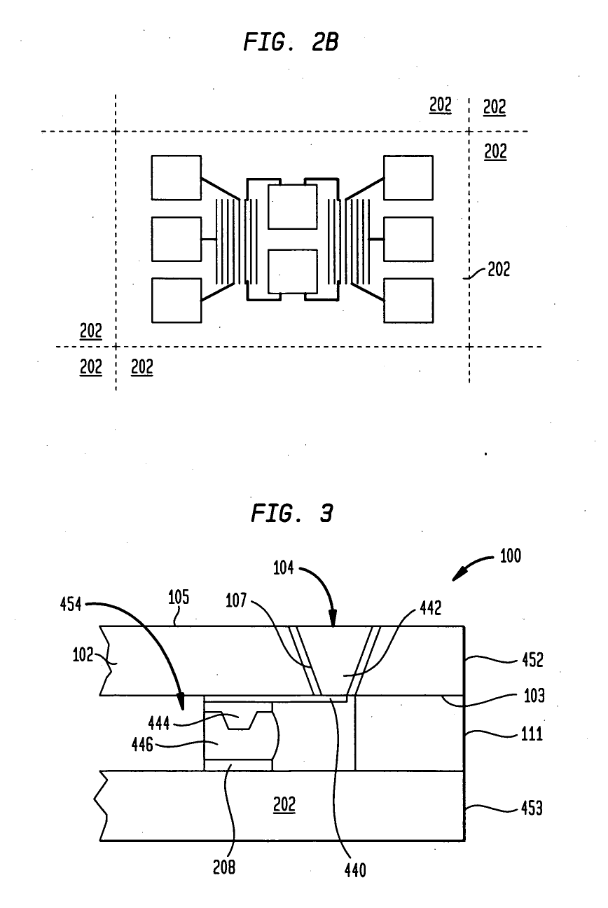

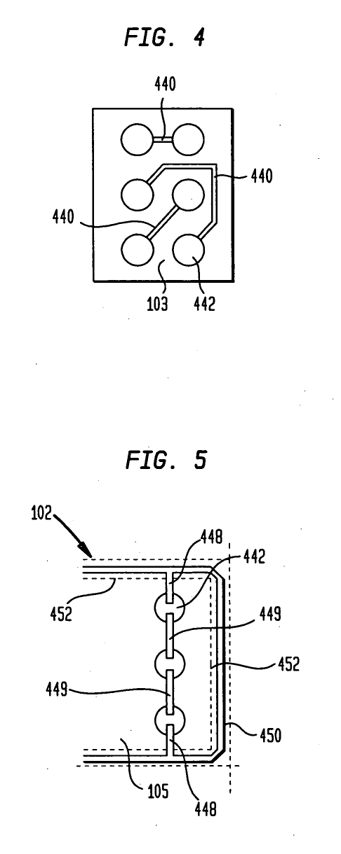

A particular embodiment of a singulated capped chip is shown in the sectional view of FIG. 3, a corresponding bottom plan view (FIG. 4) and a corresponding top plan view (FIG. 5). This embodiment and other embodiments described herein have some similarities to the structures and processing described in commonly owned U.S. patent application Ser. No. 10/949,674 filed Sep. 24, 2004, the disclosure of which is hereby incorporated by reference herein. As shown in FIG. 4, the cap 102 is mounted to the SAW device chip 202 with a conductive interconnection being made through the cap 102 from an outer surface 105 of the cap to the inner surface 103. With reference to FIGS. 3-4, in this structure, a redistribution trace 440, which may function as a “fan-out” trace, is provided on the side 103 of the cap 102 which faces the chip 202, that is, the underside of the cap, also referred to herein as the “inner surface” of the cap. The redistribution traces can function as a “fan-out” trace for the purpose of providing contacts on the cap which are disposed farther apart and at more convenient locations for higher level packaging than the locations of the bond pads of the chip. Such arrangement permits the size of the chip to be made smaller, which allows more cost-effective chip processing, because more chips are fabricated at a time on a single wafer. The cap 102 is provided of a material such as that described above, and is preferably mounted as a cap wafer containing plurality of attached caps to a device wafer containing a plurality of attached chips of a chip-containing wafer, after which the joined structure is severed into individual units.

With specific reference to FIG. 3, the redistribution traces 440 extend along the inner surface 103 of the cap from the locations of interconnecting masses 442 of conductive material which extends from the inner surface 103 to the outer surface 105 of the cap 102 by way of through holes 104. The conductive material forming the masses 442 is a flowable conductive material such as a conductively loaded polymer, one or more metals or a fusible conductive medium. Most preferably, the masses 442 are formed of a fusible conductive medium such as solder, tin or eutectic composition, and are formed in contact with a bonding layer 107 disposed on walls of the through holes. At the other end of the conductive traces, protrusions 444, such as stud bumps, are preferably provided. The protrusions 444 provide surfaces to which a bonding medium such as a conductive adhesive 446 adheres to form an electrically conductive path from the bond pads 208 of the chip 202 to the traces 440. Preferably, the adhesive is an anisotropic conductive adhesive, which conducts in a vertical direction by way of conductive elements in the adhesive that are pressed into contact between the protrusions 444 and the bond pad 208. An anisotropically conductive adhesive does not conduct in a lateral direction, i.e., in a direction parallel to trace 440, due to lateral spacing between the conductive elements of the adhesive.

Alternatively, when the protrusion 444 conductively contacts the bond pad 208, a nonconductive adhesive can be used in place of the conductive adhesive 446. Alternatively, a fusible conductive medium such as solder is used in place of the conductive adhesive. In such case, a mass of fusible material such as solder is preferably applied as a bump to the protrusion 444 or the corresponding location of the trace 440, if the protrusion is not present, before the cap wafer is bonded to the chip wafer. The cap wafer and the chip wafer are then heated to cause the solder to reflow, thus forming a solder mass bonding the two wafers in the place where the conductive adhesive 446 is shown.

In one embodiment, the cap wafer is formed by patterning a layer of metal on the cap wafer to form the redistribution traces 440, after which the through holes are formed by an etching process or other removal process which is endpointed upon reaching the redistribution traces 440. Bonding layers 107 are then formed on walls of the through holes, as needed, and the through holes are then are then filled with the conductive material, that material preferably being a fusible conductive material such as solder.

Further, each chip 202 is preferably sealed to the cap 102 by way of a seal 111 which is formed as a “picture frame ring seal” to extend along the peripheral edges 452 of the cap and the peripheral edges 453 of the chip, so as to seal the cap 102 to the chip 202 while enclosing a central void 454 occupied by a gas or a vacuum. When the chip is a SAW device chip, the seal 111 is required to be a hermetic seal to prevent ingress of moisture or other material which could alter or contaminate the SAW device, causing it to malfunction. As there is no such thing as an absolutely leak free enclosure, “hermeticity” is defined as the degree to which an enclosure protects against the leaking of material, e.g., gas or other fluid to or from the enclosure, in terms of a maximum permissible leak rate for the application. In a particular example, for many silicon semiconductor devices, a package is considered to be hermetic if is has a leak rate of helium below 1×10⁻⁸ Pa m³/sec. The hermetic package needs to provide protection during exposure to a diversity of external environments. These include normal service conditions, shipping and storage, accelerated life tests conducted for quality assurance purposes and other steps of the manufacturing and assembly process.

As shown in the top plan view of FIG. 5, a plurality of temporary ties 448 conductively connect the conductive masses which are disposed as contacts 442 on the top side 105 of the cap to a guard ring 450 which is disposed in dicing lanes outside the peripheral edges 452 of the cap. In addition, as further shown in FIG. 5, other temporary ties 449 connect adjacent ones of the conductive masses 442 to each other. The ties 448, like the ties 448, are severable after the cap 102 is joined to the chip 202, as for example, through the sawing process by which the joined assembly of the cap wafer and chip-containing wafer is singulated into individual chips.

However, the sawing process is not able to sever the temporary ties 449 which connect adjacent ones of the contacts 442 on the outer surface 105 of the cap. Accordingly, a method other than the sawing process must be used to sever the temporary ties 449. For example, the temporary ties 449 can be severed through ablation caused by laser illumination, for example.

According to one embodiment, laser illumination is available for use in ablating portions of the temporary ties which are disposed on the outer surface 105 of the cap. However, in a particular embodiment, when the cap is provided of a material which is at least partially optically transmissive to the wavelength of the laser illumination, the temporary ties can be disposed on the inner surface, rather than the outer surface of the cap. In such case, the laser illumination can be directed through the cap of the capped chip to the temporary ties disposed along the inner surface of the cap to cause ablation of the ties, and, therefore, disconnect such ties from the contacts.

Another way of severing temporary ties disposed on the outer surface of the cap is through localized heating. For example, the temporary ties can be contacted with a heated tool, e.g. probing tool, causing the ties to melt and to pull back from the location of the heated tool, for example, due to surface tension. Alternatively or in addition thereto, some of the metal may be drawn onto the probe. In one example, the heated tool contains multiple metallic prongs which are simultaneously contacted to multiple temporary ties in order to sever them all at once.

Another way that the temporary ties can be severed is through etching. After the chip wafer is joined to the cap wafer and sealed thereto to prevent ingress of moisture, an etchant can be applied to the outer surface of the cap and allowed to etch the material of the conductive ties until the conductive tie has been disconnected from the contacts. When the conductive ties are made thin in relation to the structure of the contacts, the etchant will remove the conductive ties without removing too much of the material of the contacts. Etching is an advantageous method to be used for this purpose because when the etchant is allowed to contact the whole outer surface of the cap, the etchant will not only disconnect the temporary ties, but can clean the surface of the cap sufficiently to prevent stubs from remaining after the etching operation.

Another way that the temporary ties can be severed is by mechanical abrasion. For example, polishing equipment can be used to abrade the outer surface of the capped chip such that thin temporary ties are removed from the outer surface, while leaving the contacts thereon substantially undisturbed.

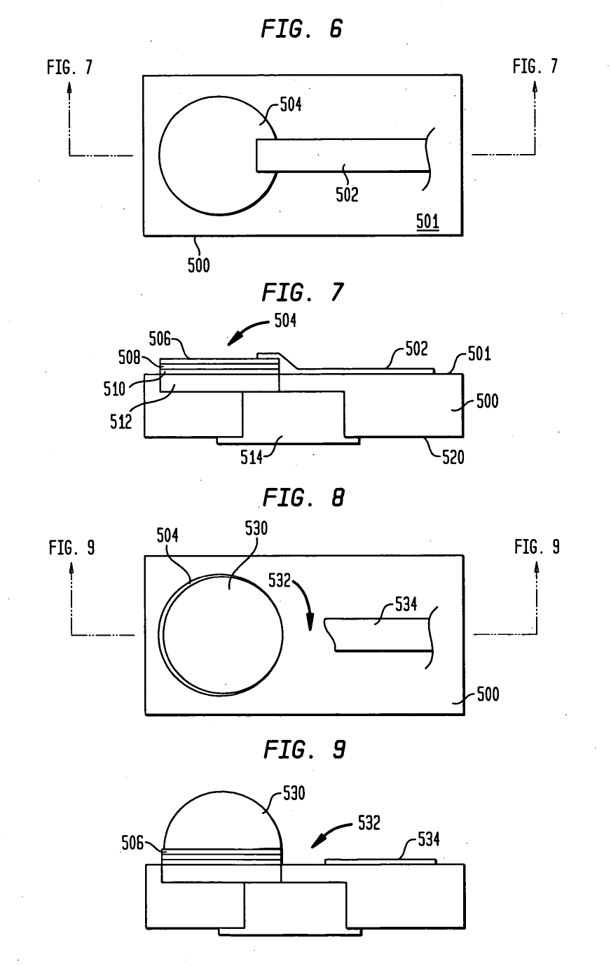

A particular embodiment of a cap having ties which are severed by a process other than sawing will now be described with reference to FIGS. 6-9. FIG. 6 is a top-down plan view and FIG. 7 is a sectional view through line 7-7 of FIG. 6, respectively. FIGS. 6-7 illustrate the structure of a cap 500 having a conductive tie 502 on an outer surface of the cap which is connected to a contact 504, the tie 502 being formed of a metal, e.g., gold, tin, or a eutectic composition, which is soluble in a fusible conductive material such as a solder. High effective solubility of the conductive tie (and guard ring, FIG. 2) structure can be achieved by a combination of the thickness of the wiring trace and the intrinsic solubility in the solder. Gold, for example, dissolves in molten solder at a rate of microns per second. Thus, a sub-micron thick tie bar of pure gold would be expected to dissolve completely during a normal solder reflow cycle.

The contact 504 is such as typically provided as a solder-bondable contact, having an under bump metallization (UBM) which includes three conductive layers: a bonding layer 506 overlying a barrier layer 508, which in turn overlies a base layer 510. As specifically shown in FIG. 7, the base layer 510 overlies a conductive feature, e.g., contact pad 512 of the cap. In turn, the contact pad 512 has a conductive interconnection to inner surface contact 514 which is exposed at a inner surface 520 of the cap 500. In the particular embodiment shown in FIG. 7, the contact pad 512 is laterally offset from the inner surface contact 514 so as to facilitate redistribution of the contacts on the cap 500 from the placement of the bond pads as exist on the chip. Alternatively, the contact pad 512 need not be laterally offset, and can be formed as a continuous structure together with the inner surface contact, extending from the outer surface of the cap to the inner surface.

In one embodiment, cap 500 includes a dielectric or semiconducting element, consisting essentially of glass, ceramic or semiconductor material, for example. In another embodiment, the cap can be formed as a conductive, e.g., metallic element on which an insulating layer (not shown) is provided for insulating the contacts, UBM, and temporary conductive ties from the metallic element.

As particularly shown in FIGS. 6 and 7, the temporary tie 502 overlaps the bonding layer 506 of the contact 504. By virtue of this overlap, during a process of applying a molten fusible conductive material, e.g., a solder, to the contact pad structure, the temporary tie 502 will also be contacted by the molten solder.

The results obtained after the molten solder contacts the contact 504 and the temporary tie are illustrated in FIGS. 8 and 9, FIG. 9 being a corresponding sectional view through lines 9-9 in FIG. 8. As shown therein, when the contact 504 and the temporary tie are contacted by a mass 530 of molten solder, the material of the temporary tie melts and pulls away from the cap 500, dissolving into the solder, and leaving behind a gap 532 and a remaining stub portion 534 of the tie. In such way, the temporary tie 502 is disconnected from the contact 504 and no longer conductively connects the contact to other conductive elements of the cap 500.

Referring again to FIG. 5, the temporary ties 449 and the contacts 442 disposed on the outer surface 105 of the cap can be formed of a metal which is soluble in a fusible conductive material, such as the temporary ties described above with reference to FIGS. 6-9. In such way, when conductive interconnection is made to the contacts 442, the temporary ties 449 dissolve into the fusible material, causing them to become disconnected from the contacts.

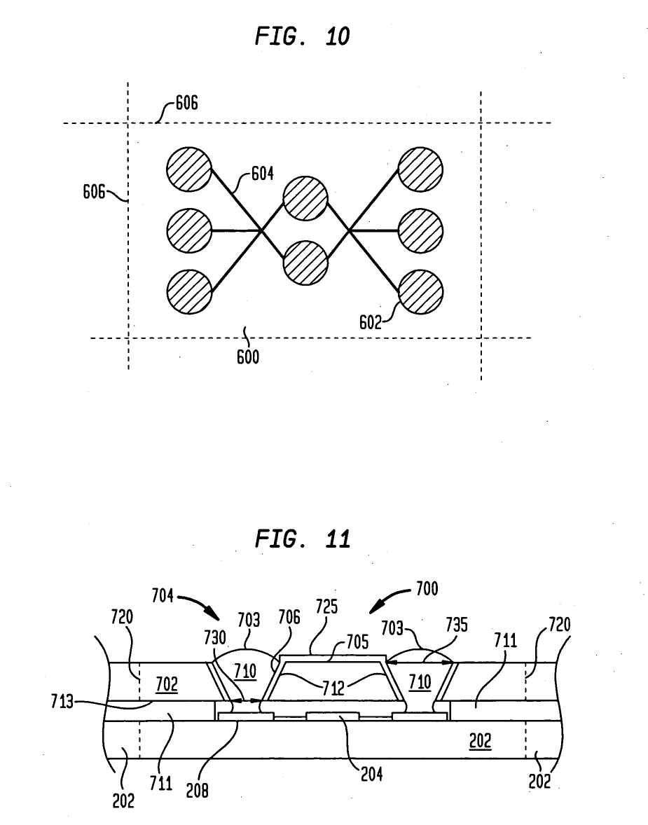

FIG. 10 is a plan view illustrating a top (outer surface) of a cap 600 in accordance with another embodiment of the invention. As shown in FIG. 10, the temporary ties 604 of the cap 600 conductively connect all of the contacts 602 exposed at the outer surface of the cap. However, unlike the embodiments shown and described above with reference to FIG. 2 and FIG. 5, the conductive guard ring is eliminated. By eliminating the guard ring, some area of the chip may be saved, because the dicing lanes 606 between the cap and adjacent caps need not made to a minimum width needed to assure that the guard ring is fully severed from the temporary ties. Another benefit achieved by the embodiment shown in FIG. 10 is that the process of singulating the joined cap wafer and chip wafer into capped chips can be disconnected from the process of severing the temporary ties. In such way, the temporary ties can be allowed to remain on the outer surface of the cap longer on the capped chip, allowing additional processes to be performed to the capped chip prior to severing the temporary ties.

FIG. 11 is a sectional view illustrating a capped chip 700 according to another embodiment of the invention, similar to that described above with reference to FIGS. 3-5. This embodiment is similar to that described in the U.S. patent application Ser. No. 10/949,674, which is incorporated herein by reference, in which conductive interconnects 704 to the bond pads 208 of the chip 202 are formed which extend through individual through holes 710 formed in the cap 702. In a preferred embodiment, one or more conductive layers 706, e.g., such that as that commonly referred to as an “under bump metallization” and described above relative to FIGS. 6-9, is disposed along interior sidewalls 712 of through holes 710, as well as extending along the outer surface 705 of the cap so as to provide a conductive interconnection between the sidewalls 712 of respective through holes 710. Alternatively, the UBMs can be disposed only along the interior sidewalls 712 of the through holes 710 while the through holes 710 are conductively connected through a conductive trace 725 formed only of a metal which is soluble in a fusible conductive material. In this way, the temporary ties can be severed through one of the above-described techniques such as dissolution into a solder, laser ablation, etching,

In the embodiment shown in FIG. 11, the conductive interconnects 704 are provided by flowing a fusible conductive material 703 such as a solder, tin, or other material onto a bonding layer 706 disposed on sidewalls of the through holes. The fusible material extends below the bottom or inner surface 713 of the cap 702 to contact the bond pad 208 of the chip 202. The fusible material 703 is preferably a high temperature solder so as to permit the capped chip 700 formed thereby to be hierarchically soldered. Stated another way, after using a high temperature to form interconnects within each capped chip 700, the capped chip 700 can be bonded through a lower melting point solder to an additional element of an assembly such as a circuit panel without disturbing the previously formed interconnects.

As in the above-described embodiment, the cap 702 is sealed to the chip 202 through a sealing medium 711, which can be hermetic for the purposes required by the device 204, e.g., such as when the chip includes a SAW device. FIG. 11 illustrates a stage of processing prior to severing the chip 202 from other chips 202 adjacent thereto along dicing lanes 720.

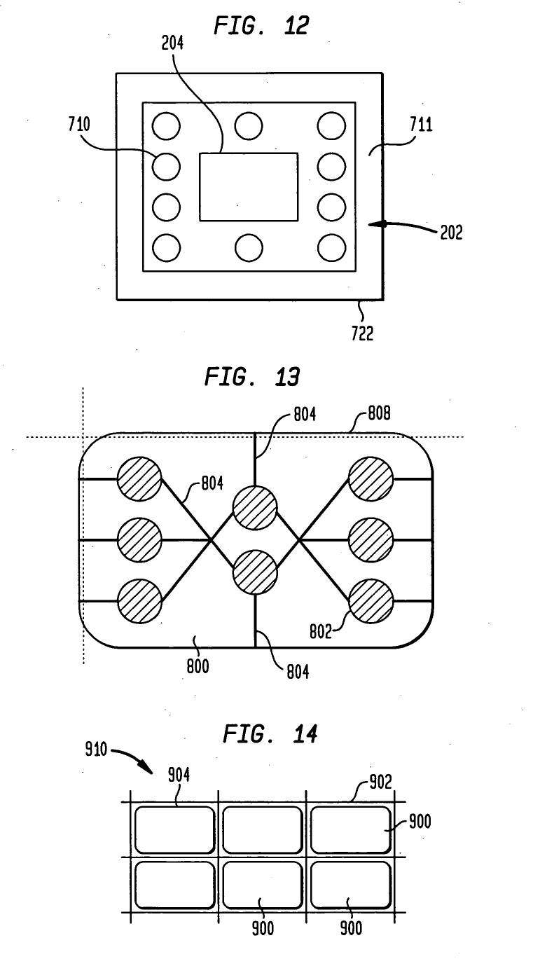

As further shown in the plan view of FIG. 12 which looks toward the device 204 of the chip 202, the peripheral seal 711 is disposed along the edges 722 of the chip (after dicing along the dicing lanes), so as to enclose the device 204 as well as the conductive interconnects 204, thus forming a sealed volume enclosing the device 204.

FIG. 13 is a plan view illustrating another embodiment of a cap 800 in which temporary ties 804 of the cap conductively and directly connect the contacts 802 provided on the cap as well as connect the contacts 802 to the guard ring 808. Such structure on cap 800 provides a robust network of ties for guarding against pyroelectric discharges, through the provision of both the guard ring and the interior ties between contacts. If either the guard ring or the interior ties fail, the remaining temporary conductive ties are still able to perform their function. In addition, when the guard ring is placed within the dicing lane, the guard ring can be severed when the joined structure of the cap wafer and chip wafer are sawn into individual singulated chips, while allowing the temporary ties of the interior to continue performing their function.

In a further embodiment shown in FIG. 14, the guard rings 904 on individual caps 900 of a cap wafer 910 are disposed within the area between the dicing lanes 902. By placing the guard ring 904 of a chip inside the dicing lanes, this assures that the temporary ties will not be severed simply as a result of the singulation process. Such result is desirable when concern remains for possibility of electrostatic discharge, e.g., through pyroelectric effects, during or even after the singulation process. Here again, one or more of the above-described post-singulation processes such as laser ablation, mechanical abrasion, etching and dissolution into a fusible conductive material can be used to sever or remove the temporary ties from the guard ring or along with the guard ring, when the need for such protection has been addressed through other ways, as by forming permanent connections between the contacts of the cap and terminals of a circuit panel.

Although the invention herein has been described with reference to particular embodiments, it is to be understood that these embodiments are merely illustrative of the principles and applications of the present invention. It is therefore to be understood that numerous modifications may be made to the illustrative embodiments and that other arrangements may be devised without departing from the spirit and scope of the present invention as defined by the appended claims.

1. A capped chip, comprising:
a chip having a front surface, a back surface opposite said front surface and a plurality of bond pads exposed at at least one of said front and back surfaces;
a cap joined to said chip, said cap overlying one of said front and back surfaces of said chip, said cap including a plurality of contacts conductively interconnected to said bond pads, and one or more temporary ties conductively connecting two or more of said contacts, said temporary ties being severable after said contacts are conductively interconnected to said bond pads.

2. A capped chip as claimed in claim 1, wherein said contacts are bonded directly to said bond pads.

3. A cap adapted to at least partially cover and provide conductive interconnection to the chip, comprising:
a plurality of contacts adapted to be conductively interconnected to bond pads of the chip, and one or more temporary ties conductively connecting two or more of said contacts, said temporary ties being severable after said contacts are conductively interconnected to said bond pads.

4. A cap as claimed in claim 3, wherein said cap has an inner surface adapted to face the bond pad bearing surface of the chip, an outer surface adapted to face away from the chip, and said plurality of contacts are exposed at at least one of said inner and outer surfaces.

5. A cap as claimed in claim 4, wherein said one or more temporary ties is exposed at at least one of said inner and outer surfaces.

6. A cap as claimed in claim 3, wherein said one or more temporary ties includes an electrically conductive ring disposed at a periphery of one of said inner and outer surfaces.

7. A cap as claimed in claim 3, wherein said one or more temporary ties conductively connects substantially all of said plurality of contacts.

8. A cap as claimed in claim 7, wherein said one or more temporary ties is removable from said cap by at least one of etching, laser ablation, mechanical abrasion, and dissolution in a fusible conductive material.

9. A cap as claimed in claim 5, wherein at least some of said temporary ties are exposed at said inner surface, and said cap is at least partially optically transmissive to wavelengths of a source of laser light capable of causing ablation of said temporary ties.

10. A capped chip, comprising:
a chip having a front surface, a back surface opposite said front surface and a plurality of bond pads exposed at said front surface;
a cap overlying and joined to said front surface of said chip, said cap having a plurality of contacts conductively interconnected to said bond pads, said cap further including one or more temporary ties conductively connecting two or more of said contacts, said temporary ties being severable after said contacts are conductively interconnected to said bond pads.

11. A capped chip as claimed in claim 10, wherein said chip is not fully operational until said at least one tie is severed.

12. A capped chip as claimed in claim 11, wherein said cap has an inner surface facing said chip, an outer surface facing away from said chip, and said plurality of contacts are exposed at at least one of said inner and outer surfaces.

13. A capped chip as claimed in claim 10, wherein said one or more temporary ties is exposed at at least one of said inner and outer surfaces.

14. A capped chip as claimed in claim 10, wherein said one or more temporary ties includes an electrically conductive ring disposed at a periphery of one of said inner and outer surfaces.

15. A capped substrate including a plurality of capped chips as claimed in claim 10, said capped chips including a plurality of said chips attached in form of a unitary substrate, said capped substrate comprising a plurality of dicing lanes defining boundaries between said capped chips, wherein at least one said temporary tie crosses at least one of said dicing lanes, such that said one temporary tie is severable by severing said capped chips along said dicing lanes.

16. A capped substrate as claimed in claim 15, further comprising a plurality of dicing lanes defining boundaries between said capped chips, wherein said one or more temporary ties does not cross said dicing lanes.

17. A capped chip as claimed in claim 10, wherein said one or more temporary ties is severable by mechanical abrasion.

18. A capped chip as claimed in claim 10, wherein said one or more temporary ties is severable by laser ablation.

19. A capped chip as claimed in claim 18, wherein said one or more temporary ties is disposed on an inner surface of said cap and said cap is at least partially optically transmissive to output of a laser capable of performing said laser ablation.

20. A capped chip as claimed in claim 10, wherein said one or more temporary ties is severable through localized heating.

21. A capped chip as claimed in claim 10, wherein said one or more temporary ties is severable by dissolution in a fusible material.

22. A capped chip as claimed in claim 21, wherein said one or more temporary ties consists essentially of gold, tin and a eutectic composition.

23. A capped chip as claimed in claim 22, wherein said one or more temporary ties is severable by etching.

24. A capped chip as claimed in claim 10, wherein said one or more temporary ties conductively connects substantially all of said plurality of contacts.

25. A capped chip as claimed in claim 10, further comprising a seal enclosing an interior space between said chip and said cap.

26. A capped chip as claimed in claim 25, wherein said chip includes a device exposed at said front surface, said cap overlies said front surface, and said seal includes a sealing medium disposed between said front surface and said cap.

27. A capped chip as claimed in claim 25, wherein said seal surrounds said plurality of bond pads.

28. A capped chip as claimed in claim 25, wherein said seal is hermetic.

29. A capped chip as claimed in claim 25, wherein said chip is operable to process an analog domain radio frequency signal, and at least one of said plurality of contacts is conductively connected to a bond pad of said chip to conduct the radio frequency signal.

30. A capped chip as claimed in claim 29, wherein said chip includes a surface acoustic wave (“SAW”) device, and said at least one contact is conductively connected to said SAW device.

31. A method of fabricating capped chips, comprising:
aligning a cap element to a substrate including a plurality of chips attached to each other at dicing lanes defining boundaries between said chips, said chips having an outer surface between said dicing lanes and bond pads exposed at said outer surface, said cap element including a plurality of contacts and one or more temporary ties conductively interconnecting said contacts;
joining said cap element to said substrate and forming conductive interconnects between said bond pads and said contacts to form capped chips; and
severing one said temporary tie of each chip after forming said conductive interconnects.

32. A method as claimed in claim 31, wherein said temporary tie is severed by severing said capped chips along said dicing lanes.

33. A method as claimed in claim 31, further comprising severing said capped chips along said dicing lanes and heating a fusible conductive material to conductively join said contacts to terminals of a circuit panel so that a material of said temporary tie dissolves into said fusible conductive material to sever said temporary tie.

34. A method as claimed in claim 33, wherein said material is gold.

35. A method as claimed in claim 31, wherein said temporary tie is severed by at least one of mechanical abrasion, ablation, etching, and localized heating.

36. A method as claimed in claim 35, wherein said cap is at least partially optically transmissive and said temporary tie is disposed on an inner side of said cap, said inner side facing said chip, said temporary tie being severed by locally heating said temporary tie by laser energy directed through said cap.
